(19) United States
(12) Patent Application Publication
(10) Pub. No.: US 2023/0342520 A1
(43) Pub. Date: Oct. 26, 2023

(54) TRAFFIC SIMULATION CONVERSION METHOD AND APPARATUS, AND COMPUTER DEVICE AND STORAGE MEDIUM

(71) Applicant: Tencent Technology (Shenzhen) Company Limited, Shenzhen (CN)

(72) Inventor: Xiangqi ZHANG, Shenzhen (CN)

(73) Assignee: Tencent Technology (Shenzhen) Company Limited, Shenzhen (CN)

(21) Appl. No.: 18/342,485

(22) Filed: Jun. 27, 2023

Related U.S. Application Data
(63) Continuation of application No. PCT/CN2022/118436, filed on Sep. 13, 2022.

(30) Foreign Application Priority Data
Oct. 28, 2021 (CN) 202111260948.7

(51) Int. Cl. G06F 30/20; G07C 5/02

(52) U.S. Cl. CPC G06F 30/20; G07C 5/02

(57) ABSTRACT

A traffic simulation conversion method and apparatus, a computer device, and a storage medium relate to the field of traffic simulation technologies. The method includes: obtaining first vehicle traffic data of a vehicle in a first traffic simulation; performing conversion according to the first vehicle traffic data to obtain second vehicle traffic data of the vehicle in a second traffic simulation; and running the second traffic simulation according to the second vehicle traffic data of the vehicle. The first traffic simulation and the second traffic simulation include one of a microscopic traffic simulation and a mesoscopic traffic simulation respectively. The first traffic simulation is different from the second traffic simulation. Vehicle traffic data of each vehicle in a traffic simulation is converted to implement vehicle-level traffic simulation conversion. Therefore, good consistency in traffic conditions before and after conversion is ensured, and traffic simulation accuracy is improved.

### CROSS-REFERENCE TO RELATED APPLICATIONS

This application is a continuation of International Application PCT/CN2022/118436 filed on Sep. 13, 2022, which claims priority to Chinese Patent Application No. 202111260948.7, entitled “TRAFFIC SIMULATION CONVERSION METHOD AND APPARATUS, COMPUTER DEVICE, AND STORAGE MEDIUM” filed on Oct. 28, 2021, both of which are hereby incorporated by reference in their entirety.

### FIELD OF THE TECHNOLOGY

This application relates to the field of traffic simulation technologies, and in particular, to a traffic simulation conversion method and apparatus, a computer device, and a storage medium.

### BACKGROUND

As a technology that uses a simulation technology to study a traffic behavior, traffic simulation tracks and describes changes of a traffic movement with time and space by establishing a mathematical model of real-time movements of a transport system in a specific period of time. According to a detail description degree, traffic simulation may be classified into macroscopic traffic simulation, mesoscopic traffic simulation, and microscopic traffic simulation.

In the related art, microscopic traffic simulation is further implemented based on a simulation result of mesoscopic traffic simulation. For example, the result of mesoscopic traffic simulation provides basic origin-destination (OD) data and a road network model for microscopic traffic simulation, and then a detail feature is further added to implement microscopic traffic simulation.

Mesoscopic-microscopic traffic simulation conversion methods in the related art are conversion for an entire road network, which cause traffic statuses before and after conversion to differ greatly. How to keep the traffic statuses before and after mesoscopic-microscopic traffic simulation conversion consistent is a problem to be solved.

### SUMMARY

Embodiments of this application provide a traffic simulation conversion method and apparatus, a computer device, and a storage medium, which may implement flexible conversion between a mesoscopic traffic simulation and a microscopic traffic simulation. The technical solutions are as follows.

An aspect provides a traffic simulation conversion method. The method is performed by a computer device. The method includes:
obtaining first vehicle traffic data of a vehicle in a first traffic simulation;
performing conversion according to the first vehicle traffic data to obtain second vehicle traffic data of the vehicle in a second traffic simulation; and
running the second traffic simulation according to the second vehicle traffic data of the vehicle.

The first traffic simulation and the second traffic simulation include one of a microscopic traffic simulation and a mesoscopic traffic simulation respectively. The first traffic simulation is different from the second traffic simulation.

Another aspect provides a traffic simulation conversion apparatus. The apparatus includes:
an obtaining module, configured to obtain first vehicle traffic data of a vehicle in a first traffic simulation;
a conversion module, configured to perform conversion according to the first vehicle traffic data to obtain second vehicle traffic data of the vehicle in a second traffic simulation; and
a running module, configured to run the second traffic simulation according to the second vehicle traffic data of the vehicle.

The first traffic simulation and the second traffic simulation include one of a microscopic traffic simulation and a mesoscopic traffic simulation respectively. The first traffic simulation is different from the second traffic simulation.

Another aspect provides a computer device. The computer device includes a processor and a memory. The memory stores at least one piece of program. The at least one piece of program is loaded and executed by the processor to implement any traffic simulation conversion method in the embodiments of this application.

Another aspect provides a computer-readable storage medium. The computer-readable storage medium stores computer instructions. The computer instructions are loaded and executed by a processor to implement the traffic simulation conversion method provided in each aspect of this application.

Another aspect provides a computer program product. The computer program product includes computer instructions. The computer instructions are stored in a computer-readable storage medium. A processor of a computer device reads the computer instructions from the computer-readable storage medium. The processor executes the computer instructions, such that the computer device performs the traffic simulation conversion method.

The technical solutions provided in the embodiments of this application have at least the following beneficial effects.

Vehicle traffic data of a specific vehicle in a traffic simulation is converted to implement a vehicle-level traffic simulation conversion method. Therefore, traffic conditions before and after conversion are substantially the same, and traffic simulation conversion accuracy and flexibility are improved.

### BRIEF DESCRIPTION OF THE DRAWINGS

FIG. 1 is a schematic diagram of an interface on which a mesoscopic traffic simulation and a microscopic traffic simulation are run simultaneously in different regions according to an embodiment of this application.

FIG. 2 is a schematic diagram of an interface on which traffic status prediction is performed according to an embodiment of this application.

FIG. 3 is a block diagram of a structure of a traffic simulation system according to an embodiment of this application.

FIG. 4 is a flowchart of a traffic simulation conversion method according to an embodiment of this application.

FIG. 5 is a flowchart of converting a mesoscopic traffic simulation to a microscopic traffic simulation according to an embodiment of this application.

FIG. 6 is a flowchart of converting vehicle traffic data of a vehicle in a mesoscopic traffic simulation to obtain vehicle traffic data in a microscopic traffic simulation according to an embodiment of this application.

FIG. 7 is a flowchart of converting a mesoscopic traffic simulation to a microscopic traffic simulation according to an embodiment of this application.

FIG. 8 is a flowchart of a traffic simulation conversion method according to an embodiment of this application.

FIG. 9 is a flowchart of converting vehicle traffic data of a vehicle in a microscopic traffic simulation to obtain a distance from a current position of the vehicle to an origin of a road in a mesoscopic traffic simulation according to an embodiment of this application.

FIG. 10 is a flowchart of converting vehicle traffic data of a vehicle in a microscopic traffic simulation to obtain landing time of the vehicle on a next road in a mesoscopic traffic simulation according to an embodiment of this application.

FIG. 11 is a flowchart of converting a microscopic traffic simulation to a mesoscopic traffic simulation according to an embodiment of this application.

FIG. 12 is a block diagram of a structure of a traffic simulation conversion apparatus according to an embodiment of this application.

FIG. 13 is a block diagram of a structure of a computer device according to an embodiment of this application.

### DETAILED DESCRIPTION

Terms involved in the embodiments of this application are first described.

Microscopic traffic simulation: a detail description degree for an element and a behavior in a traffic system is highest. For example, a microscopic traffic simulation model describes a traffic flow by taking a single vehicle as a basic unit, and may truly reflect a microscopic behavior of a vehicle on a road, for example, following, overtaking, or lane changing.

Mesoscopic traffic simulation: a mesoscopic traffic simulation model often describes a traffic flow by taking a queue including a plurality of vehicles as a unit, may describe inflow and outflow behaviors of the queue on a road section and a node, and may also simply make an approximate description about behaviors of the vehicles, for example, lane changing. Each vehicle in the mesoscopic traffic simulation may be regarded as belonging to a queue.

Microscopic map: as a map meeting a running requirement of the microscopic traffic simulation, it includes “roads” and “connecting road sections” between the roads. For example, the “connecting road section” may be understood as a junction section between two roads. Each of the “road” and the “connecting road section” in the microscopic map includes a plurality of discrete points. Information of each discrete point includes a longitude and a latitude of the discrete point.

Mesoscopic map: as a map meeting a running requirement of the mesoscopic traffic simulation, it may be regarded as a reduced version of the microscopic map, and includes “roads” and “connecting road sections” between the roads. For example, the “connecting road section” may be understood as a junction section between two roads. The “road” and the “connecting road section” in the mesoscopic map may include only length information.

Microscopic vehicle: the microscopic traffic simulation describes a traffic behavior of the vehicle in detail, for example, lane changing of the vehicle, a behavior of the vehicle at a junction, or an interaction between vehicles. Therefore, vehicle traffic data of the microscopic vehicle is more specific, for example, a longitude and a latitude of the vehicle (that is, a global coordinate of the vehicle), a front orientation of the vehicle, or a speed of the vehicle. Specifically, the vehicle traffic data of the microscopic vehicle includes at least one of vehicle traffic data shown in Table 1.

TABLE 1

| Name | Type | Description |
|---|---|---|
| Vehicle serial number | Unsigned 64-bit | Serial number uniquely |
| (vehicle_id_{micro}) | integer (uint64) | identifying the vehicle |
| Vehicle speed | Double-precision | Current travel speed of the |
| (speed_{micro}) | floating point | vehicle, in units of |
| | number (double) | meters/second |
| Serial number of the | Unsigned 64-bit | Serial number of the road |
| road section | integer (uint64) | section that the vehicle |
| (road_id_{micro}) | | is on |
| Longitude (lng_{micro}) | Double-precision | Longitude of a current |
| | floating point | position of the vehicle |
| | number (double) | |
| Latitude (lat_{micro}) | Double-precision | Latitude of the current |
| | floating point | position of the vehicle |
| | number (double) | |
| Front orientation | Double-precision | Front orientation of the |
| (yaw_{micro}) | floating point | vehicle, in units of radians |
| | number (double) | (rad) |

Mesoscopic vehicle: the mesoscopic traffic simulation may be regarded as a reduced microscopic traffic simulation, so vehicle traffic data of the mesoscopic vehicle is not as fine as that of the microscopic vehicle. The data of the mesoscopic vehicle mainly describes a relative position of the vehicle on a road section, for example, a distance from the current position of the vehicle to an origin of the road section. Specifically, the vehicle traffic data of the mesoscopic vehicle includes at least one of vehicle traffic data shown in Table 2.

TABLE 2

| Name | Type | Description |
|---|---|---|
| Vehicle serial number | Unsigned 64-bit | Serial number uniquely |
| (vehicle_idₘₑₛₒ) | integer (uint64) | identifying the vehicle |
| Vehicle speed | Double-precision | Current travel speed of the |
| (speedₘₑₛₒ) | floating point | vehicle, in units of |
| | number (double) | meters/second |
| Road section serial | Unsigned 64-bit | Serial number of the road |
| number (road_idₘₑₛₒ) | integer (uint64) | section that the vehicle is on |
| In-road-section | Double-precision | Distance from the current |
| position | floating point | position of the vehicle to the |
| (road_posₘₑₛₒ) | number (double) | origin of the road section |
| Landing time | Unsigned 64-bit | Landing time of the vehicle |
| (landing_timeₘₑₛₒ) | integer (uint64) | on a next road (if the time is |
| | | greater than 0, it indicates |
| | | that the vehicle is currently |
| | | on a connecting road section) |

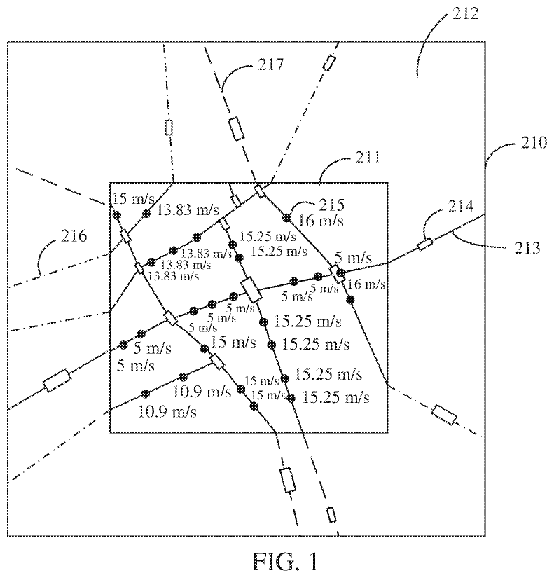

FIG. 1 is a schematic diagram of an interface on which a mesoscopic traffic simulation and a microscopic traffic simulation are run simultaneously in different regions according to an embodiment of this application.

When a user uses a “real-time simulation” function in traffic simulation, regions for the mesoscopic traffic simulation and the microscopic traffic simulation may be customized. For example, the mesoscopic traffic simulation is run in an ordinary region to obtain general traffic condition information of the ordinary region. The microscopic traffic simulation is run in a region of focus to obtain more details about a traffic status. That is, the mesoscopic traffic simulation is used for most regions in an entire map, to reduce a calculation amount and ensure running efficiency. The microscopic traffic simulation is used for a small quantity of regions of focus, to improve simulation accuracy.

During running of the “real-time simulation” function, all vehicles are traversed at fixed time intervals. When a vehicle in the mesoscopic traffic simulation region runs to the microscopic traffic simulation region, vehicle traffic data of the vehicle in the microscopic traffic simulation is determined based on vehicle traffic data of the vehicle in the mesoscopic traffic simulation, to implement conversion from the mesoscopic traffic simulation to the microscopic traffic simulation. When a vehicle in the microscopic traffic simulation region runs to the mesoscopic traffic simulation region, vehicle traffic data of the vehicle in the mesoscopic traffic simulation is determined based on vehicle traffic data of the vehicle in the microscopic traffic simulation, to implement conversion from the microscopic traffic simulation to the mesoscopic traffic simulation. Optionally, the microscopic traffic simulation region is obtained. The microscopic traffic simulation is displayed in the microscopic traffic simulation region, and the mesoscopic traffic simulation is displayed in the mesoscopic traffic simulation region other than the microscopic traffic simulation region. Microscopic traffic data is displayed in the microscopic traffic simulation region, and mesoscopic vehicle traffic data is displayed in the mesoscopic traffic simulation region. The microscopic vehicle traffic data is vehicle traffic data of a microscopic vehicle. Refer to Table 1. The microscopic vehicle traffic data includes at least one of a vehicle serial number, a vehicle speed, a road section serial number, a longitude, a latitude, and a front orientation. The mesoscopic vehicle traffic data is vehicle traffic data of a mesoscopic vehicle. Refer to Table 2. The mesoscopic vehicle traffic data includes at least one of a vehicle serial number, a vehicle speed, a road section serial number, an in-road-section position, and landing time.

For example, as shown in FIG. 1, the user designates a microscopic traffic simulation region 211 in an entire region 210, and a remaining peripheral region is a mesoscopic traffic simulation region 212. It can be seen that road sections in the microscopic traffic simulation region 211 and the mesoscopic traffic simulation region 212 include roads represented by straight lines and connecting road sections represented by blocks, for example, a road 213 represented by a straight line and a connecting road section 214 represented by a block. Vehicle traffic data of each vehicle is displayed in the microscopic traffic simulation region 211, for example, a vehicle 215 currently travels at a speed of 16 meters per second. In the mesoscopic traffic simulation region 212, a focus on the vehicle traffic data is ignored, but a road condition is described. For example, in FIG. 1, the straight line 213 represents that a current road section is congested, a dot-and-dash line 216 represents that a current road has moderate traffic, and a dashed line 217 represents that the current road is clear.

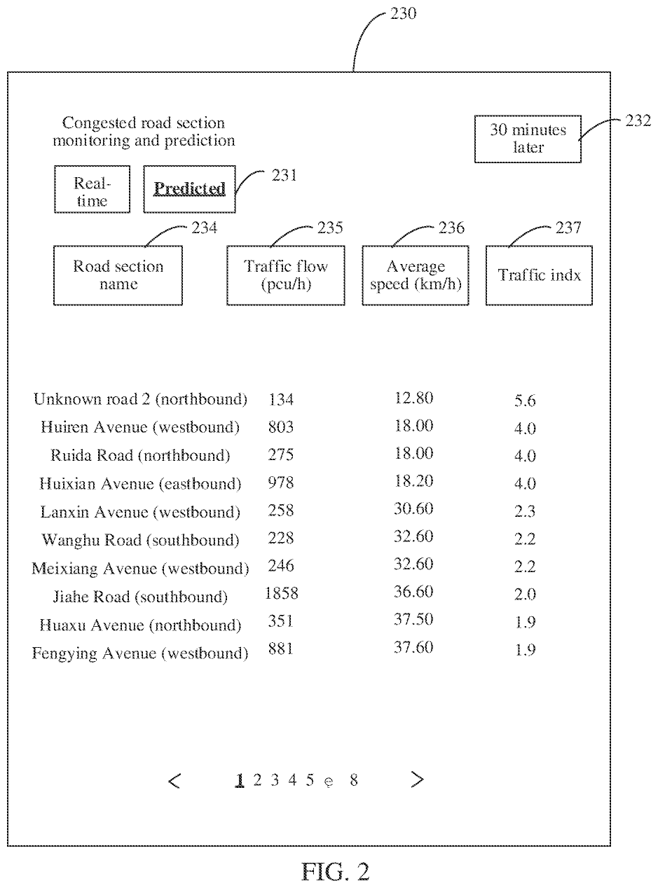

FIG. 2 is a schematic diagram of an interface on which traffic status prediction is performed according to an embodiment of this application.

During running of the microscopic traffic simulation, the user selects to turn on a function of “predicting a future traffic status”. In order to quickly simulate a future traffic status to obtain a prediction result, the microscopic traffic simulation is entirely converted to the mesoscopic traffic simulation, to efficiently and quickly obtain the prediction result with a low calculation amount. Optionally, in response to a traffic prediction operation, mesoscopic vehicle traffic data in the mesoscopic traffic simulation is determined based on microscopic vehicle traffic data in the microscopic traffic simulation. For a vehicle in a prediction region, the microscopic traffic simulation is converted to the mesoscopic traffic simulation according to the microscopic vehicle traffic data and the mesoscopic vehicle traffic data. A predicted traffic status is displayed according to the mesoscopic traffic simulation. Optionally, the traffic status is used for representing clearness of a road, and a larger numerical value represents smoother traffic. Optionally, the traffic status is used for representing a congestion degree of a road, and a larger numerical value represents more congested traffic. Optionally, the traffic status includes at least one of congested, clear, and in accident.

For example, the user taps a prediction control 231 on a traffic simulation platform interface 230 to enable the function of “predicting a future traffic status”, and sets future time 232 to be 30 minutes later. Vehicle traffic data of all vehicles in the microscopic traffic simulation at a current moment is stored, and vehicle traffic data in the mesoscopic traffic simulation is determined based on the vehicle traffic data in the microscopic traffic simulation, to convert, for all the vehicles, the microscopic traffic simulation to the mesoscopic traffic simulation. After conversion, the mesoscopic traffic simulation is run for specific time to obtain a predicted traffic status 30 minutes later. The predicted traffic status 30 minutes later is displayed on the traffic simulation platform interface 230, including a road section name 234, a traffic flow 235, an average speed 236, and a traffic index 237. The road section name 234 includes a direction of a road. The traffic flow 235 takes vehicles/hour as a unit. That is, the traffic flow 235 is a quantity of vehicles passing through the road in an hour. The average speed 236 takes kilometers/hour as a unit, that is, an average hourly speed of the vehicles passing through the road. The traffic index 237 is a conceptual index that comprehensively reflects whether the road is clear or congested, and a larger numerical value represents more congested traffic.

As described above, FIG. 1 and FIG. 2 respectively show traffic simulation conversion of some regions involved in the mesoscopic traffic simulation and the microscopic traffic simulation that are respectively performed on different regions at a same moment and entire conversion involved in the mesoscopic traffic simulation and the microscopic traffic simulation that are performed on a same region at different moments respectively, which are performed by using a traffic simulation conversion method of this application. An implementation of the traffic simulation conversion method is described in detail in the following embodiment.

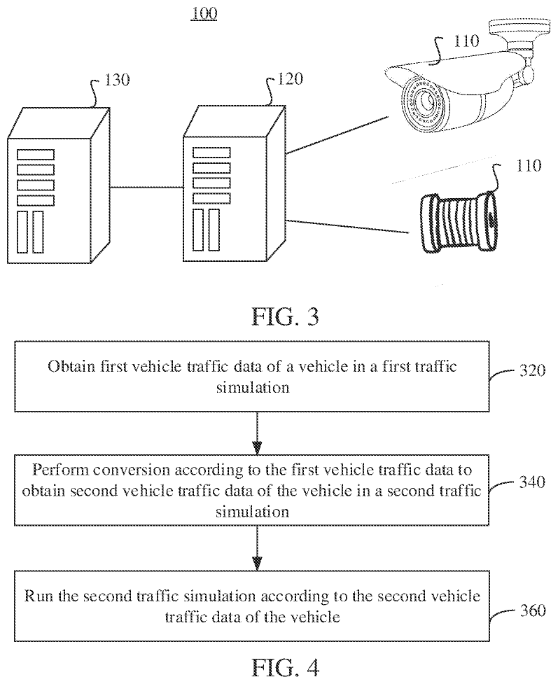

FIG. 3 is a block diagram of a structure of a traffic simulation system according to an embodiment of this application. The traffic simulation system 100 includes a sensor 110, a road data server 120, and a traffic simulation server 130.

The sensor 110 may be a camera in a road network system, a geomagnetic coil arranged under a pavement, or the like. The sensor 110 is configured to obtain road data, for example, a quantity of vehicles passing through a road, an hourly speed of a vehicle, or a traffic behavior of the vehicle.

The sensor 110 is connected to the road data server 120 by using a wireless network or a wired network.

The road data server 120 is configured to summarize the data collected by the sensor 110, and perform corresponding processing. The road data obtained by the sensor 110 is summarized and processed to obtain vehicle traffic data available for a traffic simulation. The road data server 120 includes at least one of one server, a plurality of servers, a cloud computing platform, and a virtual center.

The road data server 120 is connected to the traffic simulation server 130 by using the wired network or the wireless network.

The traffic simulation server 130 is configured to run the traffic simulation according to the vehicle traffic data obtained by the road data server 120 through summarization and processing, and implement conversion between different traffic simulation modes. The traffic simulation server 130 includes at least one of one server, a plurality of servers, a cloud computing platform, and a virtual center.

It may be understood by a person skilled in the art that there may be more or fewer sensors 110, road data servers 120, and traffic simulation servers 130. For example, there may be only one sensor 110, road data server 120, and traffic simulation server 130, or there may be dozens or hundreds of or more sensors 110, road data servers 120, and traffic simulation servers 130. A quantity and a device type of the sensor or the server are not limited in this embodiment of this application.

FIG. 4 is a flowchart of a traffic simulation conversion method according to an embodiment of this application. The method is applied to a terminal 120 or a server 140 shown in FIG. 3. As shown in FIG. 4, the method includes the following steps:

Step 320: Obtain first vehicle traffic data of a vehicle in a first traffic simulation.

The first traffic simulation includes one of a microscopic traffic simulation and a mesoscopic traffic simulation.

The microscopic traffic simulation is a more detailed traffic simulation mode more than the mesoscopic traffic simulation. Therefore, vehicle traffic data of a microscopic vehicle in the microscopic traffic simulation is more specific and accurate than that in the mesoscopic traffic simulation. The vehicle traffic data in the microscopic traffic simulation is shown in Table 1. The vehicle traffic data in the mesoscopic traffic simulation is shown in Table 2.

For example, when the first traffic simulation is the mesoscopic traffic simulation, the first vehicle traffic data includes a serial number of a road section that the vehicle is on and a distance from a current position of the vehicle to an origin of the road section.

For example, when the first traffic simulation is the microscopic traffic simulation, the first vehicle traffic data includes a serial number of a road section that the vehicle is on, a longitude and a latitude of the vehicle, and a speed of the vehicle.

Step 340: Perform conversion according to the first vehicle traffic data to obtain second vehicle traffic data of the vehicle in a second traffic simulation.

The second includes one of the microscopic traffic simulation and the mesoscopic traffic simulation. The first traffic simulation is different from the second traffic simulation.

For example, when the first traffic simulation includes the mesoscopic traffic simulation, and the second traffic simulation includes the microscopic traffic simulation, it can be seen according to data content in vehicle traffic data of a microscopic vehicle and vehicle traffic data of a mesoscopic vehicle that the distance from the current position of the vehicle to the origin of the road section in the mesoscopic traffic simulation is to be converted to obtain the longitude and the latitude of the vehicle and a front orientation of the vehicle in the microscopic traffic simulation.

That is, the second vehicle traffic data includes the longitude and the latitude of the vehicle and the front orientation of the vehicle.

That is, conversion is performed according to the serial number of the road section that the vehicle is on and the distance from the current position of the vehicle to the origin of the road section to obtain the second vehicle traffic data of the vehicle in the microscopic traffic simulation, and the second vehicle traffic data includes the longitude and the latitude of the vehicle and the front orientation of the vehicle.

Further, the road section in a mesoscopic map and a microscopic map includes at least one of a road and a connecting road section.

For example, when a type of the road section that the vehicle is on is the road, the longitude and the latitude of the vehicle are determined according to a serial number of the road that the vehicle is on and a distance from the current position of the vehicle to an origin of the road, and the front orientation of the vehicle is determined according to the serial number of the road that the vehicle is on and the distance from the current position of the vehicle to the origin of the road.

For example, when a type of the road section that the vehicle is on is the connecting road section, the longitude and the latitude of the vehicle are determined according to a serial number of the connecting road section that the vehicle is on and a distance from the current position of the vehicle to an origin of the connecting road section, and the front orientation of the vehicle is determined according to the serial number of the connecting road section that the vehicle is on and the distance from the current position of the vehicle to the origin of the connecting road section.

For example, when the first traffic simulation includes the microscopic traffic simulation, and the second traffic simulation includes the mesoscopic traffic simulation, it can be seen according to data content in vehicle traffic data of a microscopic vehicle and vehicle traffic data of a mesoscopic vehicle that the longitude and the latitude of the vehicle in the microscopic traffic simulation is to be converted to obtain the distance from the current position of the vehicle to the origin of the road section and landing time of the vehicle on a next road in the mesoscopic traffic simulation.

That is, the second vehicle traffic data includes the distance from the current position of the vehicle to the origin of the road section and the landing time of the vehicle on the next road. The landing time of the vehicle on the next road is a parameter set for a vehicle on a connecting road section. When the parameter is greater than 0, it indicates that the current position of the vehicle is on the connecting road section.

That is, step 340 includes at least one of the following sub-steps: performing conversion according to the serial number of the road section that the vehicle is on and the longitude and the latitude of the vehicle to obtain the distance from the current position of the vehicle to the origin of the road section in the mesoscopic traffic simulation; and performing conversion according to the serial number of the road section that the vehicle is on, the longitude and the latitude of the vehicle, and the speed of the vehicle to obtain the landing time of the vehicle on the next road in the mesoscopic traffic simulation.

Further, the road section in the mesoscopic map and the microscopic map includes at least one of the road and the connecting road section.

For example, when the type of the road section that the vehicle is on is the road, conversion is performed according to the serial number of the road section that the vehicle is on and the longitude and the latitude of the vehicle to obtain the distance from the current position of the vehicle to the origin of the road section in the mesoscopic traffic simulation.

For example, when the type of the road section that the vehicle is on is the connecting road section, conversion is performed according to the serial number of the road section that the vehicle is on, the longitude and the latitude of the vehicle, and the speed of the vehicle to obtain the landing time of the vehicle on the next road in the mesoscopic traffic simulation.

In a possible implementation, when the type of the road section that the vehicle is on is the connecting road section, conversion is performed according to the serial number of the road section that the vehicle is on and the longitude and the latitude of the vehicle to obtain the distance from the current position of the vehicle to the origin of the connecting road section in the mesoscopic traffic simulation.

Step 360: Run the second traffic simulation according to the second vehicle traffic data of the vehicle.

The second traffic simulation is run based on the obtained second vehicle traffic data of the vehicle.

When the second traffic simulation is the microscopic traffic simulation, the microscopic traffic simulation is run according to the longitude and the latitude of the vehicle and the front orientation of the vehicle.

When the second traffic simulation is the mesoscopic traffic simulation, the mesoscopic traffic simulation is run according to the distance from the current position of the vehicle to the origin of the road section and the landing time of the vehicle on the next road.

In summary, in this embodiment of this application, conversion is performed based on the obtained first vehicle traffic data in the first traffic simulation to obtain the second vehicle traffic data of the vehicle in the second traffic simulation, and then the second traffic simulation is performed. In this method, vehicle traffic data of each vehicle is sequentially converted to implement vehicle-level conversion between the mesoscopic traffic simulation and the microscopic traffic simulation. Therefore, the vehicles may remain consistent before and after traffic simulation conversion, the problem that traffic statuses before and after conversion differ excessively due to a change in a traffic simulation mode is solved, and traffic simulation conversion accuracy is improved.

An implementation process of converting the first traffic simulation to the second traffic simulation is described in the foregoing embodiment.

An implementation process of converting a mesoscopic traffic simulation to a microscopic traffic simulation is specifically described in the following embodiment.

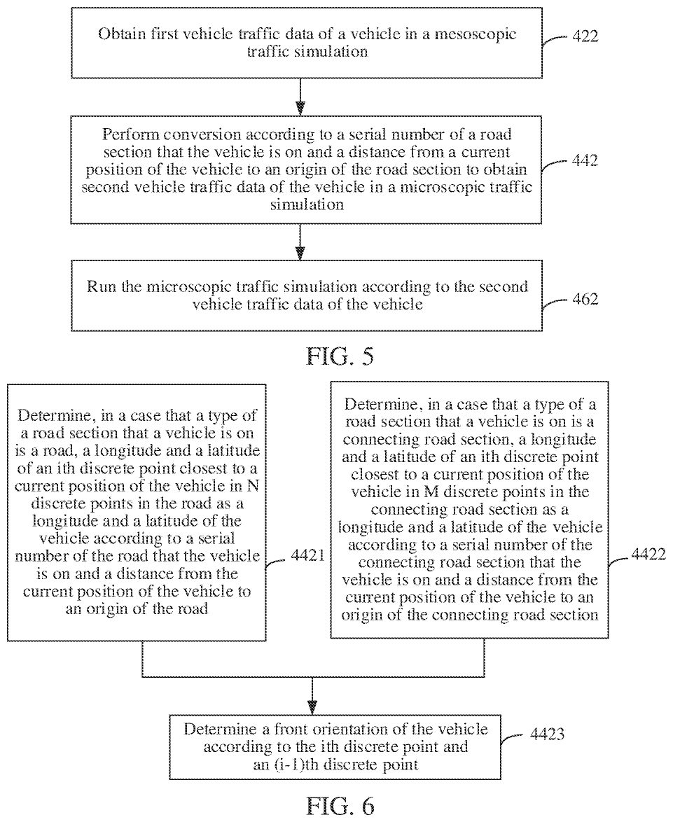

FIG. 5 is a flowchart of converting the mesoscopic traffic simulation to the microscopic traffic simulation according to an embodiment of this application. The method is applied to a terminal 120 or a server 140 shown in FIG. 3. As shown in FIG. 5, the method includes the following steps:

Step 422: Obtain first vehicle traffic data of a vehicle in the mesoscopic traffic simulation.

When a first traffic simulation is the mesoscopic traffic simulation, that is, an initial traffic simulation mode is the mesoscopic traffic simulation, data of a mesoscopic vehicle is obtained to implement conversion from the mesoscopic vehicle to a microscopic vehicle.

For example, the first vehicle traffic data includes a serial number of a road section that the vehicle is on and a distance from a current position of the vehicle to an origin of the road section.

Step 442: Perform conversion according to the serial number of the road section that the vehicle is on and the distance from the current position of the vehicle to the origin of the road section to obtain second vehicle traffic data of the vehicle in the microscopic traffic simulation.

When the first traffic simulation is the mesoscopic traffic simulation, a second traffic simulation is the microscopic traffic simulation. That is, conversion is to be performed based on the first vehicle traffic data of the vehicle in the mesoscopic traffic simulation to obtain the second vehicle traffic data to be used in the microscopic traffic simulation.

For example, the second vehicle traffic data includes a longitude and a latitude of the vehicle and a front orientation of the vehicle.

In a microscopic map and a mesoscopic map, the road section includes a road and a connecting road section between roads. Descriptions about the vehicle on the road and on the connecting road section differ greatly, so the road and the connecting road section are distinguished to implement conversion of the vehicle traffic data respectively.

For example, when a type of the road section that the vehicle is on is the road, the longitude and the latitude of the vehicle are determined according to a serial number of the road that the vehicle is on and a distance from the current position of the vehicle to an origin of the road, and the front orientation of the vehicle is determined according to the serial number of the road that the vehicle is on and the distance from the current position of the vehicle to the origin of the road.

For example, when a type of the road section that the vehicle is on is the connecting road section, the longitude and the latitude of the vehicle are determined according to a serial number of the connecting road section that the vehicle is on and a distance from the current position of the vehicle to an origin of the connecting road section, and the front orientation of the vehicle is determined according to the serial number of the connecting road section that the vehicle is on and the distance from the current position of the vehicle to the origin of the connecting road section.

The following describes step 442 more specifically. FIG. 6 is a flowchart of converting the vehicle traffic data of the vehicle in the mesoscopic traffic simulation to obtain the vehicle traffic data in the microscopic traffic simulation according to an embodiment of this application.

It can be seen from the foregoing description about the microscopic map that the road in the microscopic traffic simulation includes N discrete points arranged in order, N being a positive integer, and the connecting road section in the microscopic traffic simulation includes M discrete points arranged in order, M being a positive integer.

Step 4421: Determine, when the type of the road section that the vehicle is on is the road, a longitude and a latitude of an i^{th} discrete point closest to the current position of the vehicle in the N discrete points in the road as the longitude and the latitude of the vehicle according to the serial number of the road that the vehicle is on and the distance from the current position of the vehicle to the origin of the road.

N is a positive integer, and i is a positive integer less than N.

For example, step 4421 may be split into the following sub-steps:

(1): Obtain a distance between adjacent discrete points in the N discrete points according to the serial number of the road that the vehicle is on.

For example, search is performed in the microscopic map for the road that the vehicle is on according to the serial number road_idₘₑₛₒ of the road that the vehicle is on in the first vehicle traffic data. The road includes the N discrete points P₁, P₂, . . . , and P_{N} arranged in order. P₁ is the origin of the road. The distance between the adjacent discrete points in the N discrete points is obtained.

Each road has direction information. For example, in two south-north lanes, the southbound lane and the northbound lane correspond to different road serial numbers. That is, an origin P₁ of each road is uniquely determined.

(2): Determine a distance from each of the N discrete points in the road to the origin of the road by accumulating the distance between the adjacent discrete points.

For example, distances from the N discrete points in the road to the origin of the road are sequentially calculated by accumulating the distance between the adjacent discrete points from the origin P₁ of the road. A specific calculation formula is as follows:

$$dis\_to {\_start}_{j} = \{ \begin{matrix}0 & j = 1 \\ dis\_to {\_start}_{j - 1} + distance ( {p}_{j - 1} , {p}_{j} ) & j > 1\end{matrix} ,$$

where dis_to_startⱼ represents a distance from a j^{th} discrete point to the origin of the road, distance(pⱼ₋₁, pⱼ) represents a distance from a (j−1)^{th} discrete point Pⱼ₋₁ to the j^{th} discrete point Pⱼ, and j is a positive integer less than N.

That is, a distance from the first discrete point to the origin of the road is 0, a distance from the second discrete point to the origin of the road is a distance from the first discrete point to the second discrete point, a distance from the third discrete point to the origin of the road is a sum of the distance from the second discrete point to the origin of the road and a distance from the third discrete point to the second discrete point, and so on. The distances from the N discrete points to the origin of the road are respectively determined by sequential accumulation.

Since the distance between the adjacent discrete points is short, a road bend and other factors may be ignored, and the distance between the adjacent discrete points is approximately represented by a straight line length.

(3): Calculate a difference between the distance from each of the N discrete points to the origin of the road and the distance from the current position of the vehicle to the origin of the road.

After the distances from the N discrete points to the origin of the road are obtained in the previous sub-step, the difference between the distance from each of the N discrete points to the origin of the road and the distance from the current position of the vehicle to the origin of the road is calculated, that is, dis_to_startⱼ−road_posₘₑₛₒ, to obtain a distance from each of the N discrete points to the current position of the vehicle.

(4): Determine the longitude and the latitude of the i^{th} discrete point corresponding to a minimum difference as the longitude and the latitude of the vehicle, i being a positive integer less than or equal to N.

For example, the longitude and the latitude of the i^{th} discrete point corresponding to the minimum difference is determined as the longitude and the latitude of the vehicle. That is, the longitude and the latitude of the i^{th} discrete point closest to the current position of the vehicle are approximate to the longitude and the latitude of the vehicle. That is, j making the following formula minimum is assigned to i:

min_{1<j<N}(dis_to_startⱼ−road_posₘₑₛₒ).

For example, a position of the i^{th} discrete point is determined as the current position of the vehicle, and the longitude and the latitude of the i^{th} discrete point are determined as the longitude and the latitude of the vehicle.

Optionally, the road section in the microscopic map is described by using a function. That is, a sub-step of sampling the function for describing the road section to obtain the discrete points is added before sub-step (1).

Step 4422: Determine, when the type of the road section that the vehicle is on is the connecting road section, a longitude and a latitude of an i^{th} discrete point closest to the current position of the vehicle in the M discrete points in the connecting road section as the longitude and the latitude of the vehicle according to the serial number of the connecting road section that the vehicle is on and the distance from the current position of the vehicle to the origin of the connecting road section.

For example, like step 4421, step 4422 may be split into the following sub-steps:

(1): Obtain a distance between adjacent discrete points in the M discrete points according to the serial number of the connecting road section that the vehicle is on.

For example, search is performed in the microscopic map for the connecting road section that the vehicle is on according to the serial number road_idₘₑₛₒ of the connecting road section that the vehicle is on in the first vehicle traffic data. The connecting road section includes the M discrete points P₁, P₂, . . . , and P_{M} arranged in order. P1 is the origin of the connecting road section. The distance between the adjacent discrete points in the M discrete points is obtained.

Like the road, each connecting road section has direction information. That is, an origin P₁ of each connecting road section is uniquely determined.

(2): Determine a distance from each of the M discrete points in the connecting road section to the origin of the connecting road section by accumulating the distance between the adjacent discrete points.

For example, distances from the M discrete points in the connecting road section to the origin of the connecting road section are sequentially calculated by accumulating the distance between the adjacent discrete points from the origin P₁ of the connecting road section. A specific calculation formula is as follows:

$$dis\_to {\_start}_{j} = \{ \begin{matrix}0 & j = 1 \\ dis\_to {\_start}_{j - 1} + distance ( {p}_{j - 1} , {p}_{j} ) & j > 1\end{matrix} ,$$

where dis_to_startⱼ represents a distance from a j^{th} discrete point to the origin of the connecting road section, distance(pⱼ₋₁, pⱼ) represents a distance from a (j−1)^{th} discrete point Pⱼ₋₁ to the j^{th} discrete point Pⱼ, and j is a positive integer less than M.

That is, a distance from the first discrete point to the origin of the connecting road section is 0, a distance from the second discrete point to the origin of the connecting road section is a distance from the first discrete point to the second discrete point, a distance from the third discrete point to the origin of the connecting road section is a sum of the distance from the second discrete point to the origin of the connecting road section and a distance from the third discrete point to the second discrete point, and so on. The distances from the M discrete points to the origin of the connecting road section are respectively determined by sequential accumulation.

Since the distance between the adjacent discrete points is short, a road bend and other factors may be ignored, and the distance between the adjacent discrete points is approximately represented by a straight line length.

(3): Calculate a difference between the distance from each of the M discrete points to the origin of the connecting road section and the distance from the current position of the vehicle to the origin of the connecting road section.

After the distances from the M discrete points to the origin of the connecting road section are obtained in the previous sub-step, the difference between the distance from each of the M discrete points to the origin of the connecting road section and the distance from the current position of the vehicle to the origin of the connecting road section is calculated, that is, dis_to_startⱼ−road_posₘₑₛₒ, to obtain a distance from each of the M discrete points to the current position of the vehicle.

(4): Determine the longitude and the latitude of the i^{th} discrete point corresponding to a minimum difference as the longitude and the latitude of the vehicle, i being a positive integer less than or equal to M.

For example, the longitude and the latitude of the i^{th} discrete point corresponding to the minimum difference is determined as the longitude and the latitude of the vehicle. That is, the longitude and the latitude of the i^{th} discrete point closest to the current position of the vehicle are approximate to the longitude and the latitude of the vehicle. That is, j making the following formula minimum is assigned to i:

min_{1<j<M}(dis_to_startⱼ−road_posₘₑₛₒ).

For example, a position of the i^{th} discrete point is determined as the current position of the vehicle, and the longitude and the latitude of the i^{th} discrete point are determined as the longitude and the latitude of the vehicle.

Optionally, the road section in the microscopic map is described by using a function. That is, a sub-step of sampling the function for describing the road section to obtain the discrete points is added before sub-step (1).

Step 4421 and step 4422 are not both performed, but only one is to be performed according to the type of the road section that the vehicle is currently on. When the type of the road section that the vehicle is on is the road, step 4421 is performed. When the type of the road section that the vehicle is on is the connecting road section, step 4422 is performed.

Step 4423: Determine the front orientation of the vehicle according to the i^{th} discrete point and an (i−1)^{th} discrete point.

The front orientation of the vehicle is used for indicating a travel direction of the vehicle, and may be represented by a direction of a travel trajectory of the vehicle with a small value nearby the current position of the vehicle.

The i^{th} discrete point closest to the current position of the vehicle may be determined in the foregoing sub-steps. That is, the position of the i^{th} discrete point is approximately represented as the current position of the vehicle. A travel trajectory of the vehicle is obtained within a small range nearby the position, and a direction of the travel trajectory is determined as the travel direction of the vehicle.

In a possible implementation, the front orientation of the vehicle is determined according to the i^{th} discrete point and the (i−1)^{th} discrete point. Specifically, an angle of a connecting line of the i^{th} discrete point and the (i−1)^{th} discrete point in a world coordinate system (global coordinate system) is determined as the front orientation of the vehicle.

In a possible implementation, the front orientation of the vehicle is determined according to the i^{th} discrete point and an (i+1)^{th} discrete point. Specifically, an angle of a connecting line of the i^{th} discrete point and the (i+1)^{th} discrete point in a world coordinate system (global coordinate system) is determined as the front orientation of the vehicle.

A unit of the front orientation is a radian (rad). That is, the front orientation is represented by an angle. The angle is an angle of the front orientation relative to the world coordinate system (the global coordinate system) rather than an angle relative to the road section that the vehicle is currently on.

Step 462: Run the microscopic traffic simulation according to the second vehicle traffic data of the vehicle.

For example, the microscopic traffic simulation is run based on the obtained longitude and latitude of the vehicle and the front orientation of the vehicle.

The microscopic traffic simulation focuses on a behavior of each vehicle, for example, lane changing of the vehicle, turning of the vehicle, a traffic behavior of the vehicle at a junction, or an interaction between the vehicle and another vehicle.

In addition, the process of converting the mesoscopic traffic simulation to the microscopic traffic simulation in the traffic simulation conversion method of this application may be more directly presented by using an input information flow and an output information flow.

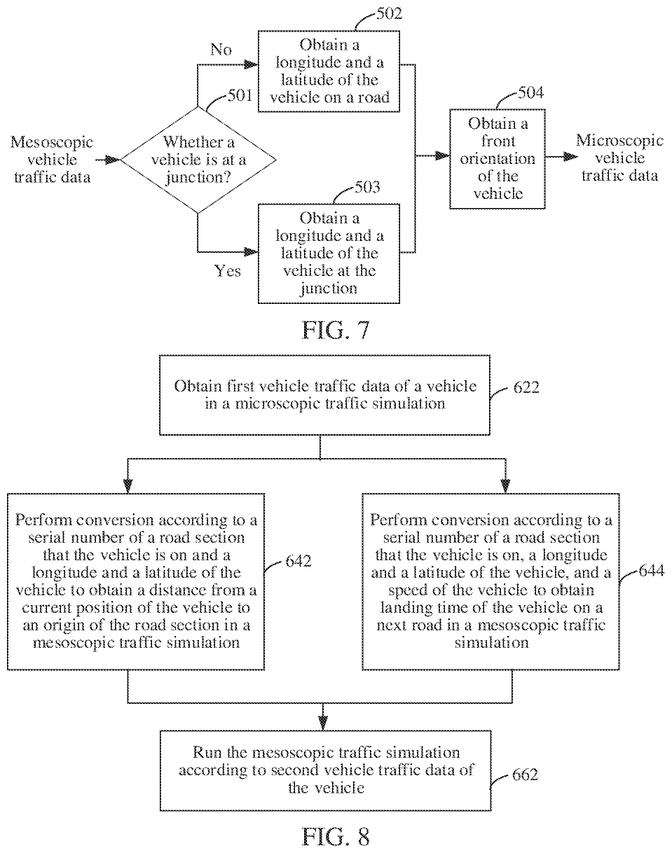

FIG. 7 is a flowchart of converting the mesoscopic traffic simulation to the microscopic traffic simulation according to an embodiment of this application.

It can be seen from FIG. 7 that the input information flow is mesoscopic vehicle traffic data, specifically a serial number of a road section that a mesoscopic vehicle is on and a distance from a current position of the mesoscopic vehicle to an origin of the road section.

Step 501: Determine whether the vehicle is at a junction. If the vehicle is not at the junction, step 502 is performed; or if the vehicle is at the junction, step 503 is performed.

Step 502: Obtain a longitude and a latitude of the vehicle on a road according to the method in step 4421 in the foregoing embodiment.

Step 503: Obtain a longitude and a latitude of the vehicle at the junction according to the method in step 4422 in the foregoing embodiment.

Step 504: Obtain, by using the method in step 4423 in the foregoing embodiment, a front orientation of the vehicle based on a position of an i^{th} discrete point that is determined in step 502 or step 503 and that is closest to the current position of the vehicle.

Finally, the output information flow in the traffic simulation conversion method in this embodiment of this application is microscopic vehicle traffic data, specifically a longitude and a latitude of the vehicle and a front orientation of the vehicle.

In summary, in this embodiment of this application, information of the discrete points in the road section is obtained by using the obtained serial number of the road section that the vehicle is on. The discrete point closest to the current position of the vehicle is determined in combination with the information of the discrete points and the distance from the current position of the vehicle to the origin of the road section. The longitude and the latitude of the vehicle and the front orientation of the vehicle are determined by combining the longitude and the latitude of the discrete point and information of discrete points nearby the discrete point. In this way, conversion of the mesoscopic traffic simulation to the microscopic traffic simulation is implemented. In the method, a method for converting a mesoscopic traffic simulation to a microscopic traffic simulation is provided. All vehicles are traversed, and conversion is performed according to vehicle traffic data of each vehicle. Therefore, consistency of data before and after conversion is ensured, the problem of a significant deviation between traffic conditions before and after conversion is solved, and traffic simulation conversion accuracy is improved.

In addition, the road section is represented by discrete points, so that traffic simulation conversion may be implemented at any position of the road section. This may not only implement conversion for an entire region but also run different traffic simulation modes for different regions at the same moment. Therefore, flexibility is high.

Moreover, the vehicle traffic data of the mesoscopic vehicle, the vehicle traffic data of the microscopic vehicle, and the microscopic map, on which this method is based, are all simply represented, and may be easily applied to conversion of various microscopic simulations and mesoscopic simulations.

A process of converting a microscopic traffic simulation to a mesoscopic traffic simulation is specifically described in the following embodiment.

FIG. 8 is a flowchart of a traffic simulation conversion method according to an embodiment of this application. The method is applied to a terminal 120 or a server 140 shown in FIG. 3. As shown in FIG. 8, the method includes the following steps:

Step 622: Obtain first vehicle traffic data of a vehicle in the microscopic traffic simulation.

When a first traffic simulation is the microscopic traffic simulation, that is, an initial traffic simulation mode is the microscopic traffic simulation, data of a microscopic vehicle is obtained to implement conversion from the microscopic vehicle to a mesoscopic vehicle.

For example, the first vehicle traffic data includes a serial number of a road section that the vehicle is on, a longitude and a latitude of the vehicle, and a speed of the vehicle.

When the first traffic simulation is the microscopic traffic simulation, a second traffic simulation is the mesoscopic traffic simulation. That is, conversion is to be performed based on the first vehicle traffic data of the vehicle in the microscopic traffic simulation to obtain second vehicle traffic data to be used in the mesoscopic traffic simulation.

Step 642: Perform conversion according to the serial number of the road section that the vehicle is on and the longitude and the latitude of the vehicle to obtain a distance from a current position of the vehicle to an origin of the road section in the mesoscopic traffic simulation.

For example, information about the road section that the vehicle is on, including information about a discrete point on the road section that the vehicle is on, is obtained by using the serial number of the road section that the vehicle is on. A discrete point closest to the current position of the vehicle is determined according to the longitude and the latitude of the vehicle and a longitude and a latitude of the discrete point, and a distance from the discrete point to the origin of the road section is calculated. The distance from the current position of the vehicle to the origin of the road is approximately obtained according to the distance from the discrete point to the origin of the road section and a distance from the discrete point to the current position of the vehicle.

For example, an example in which the road section is a road is used to describe step 642 more specifically. A case in which the road section is a connecting road section is similar to this case, and will not be elaborated. The road in the microscopic traffic simulation includes N discrete points arranged in order, N being a positive integer.

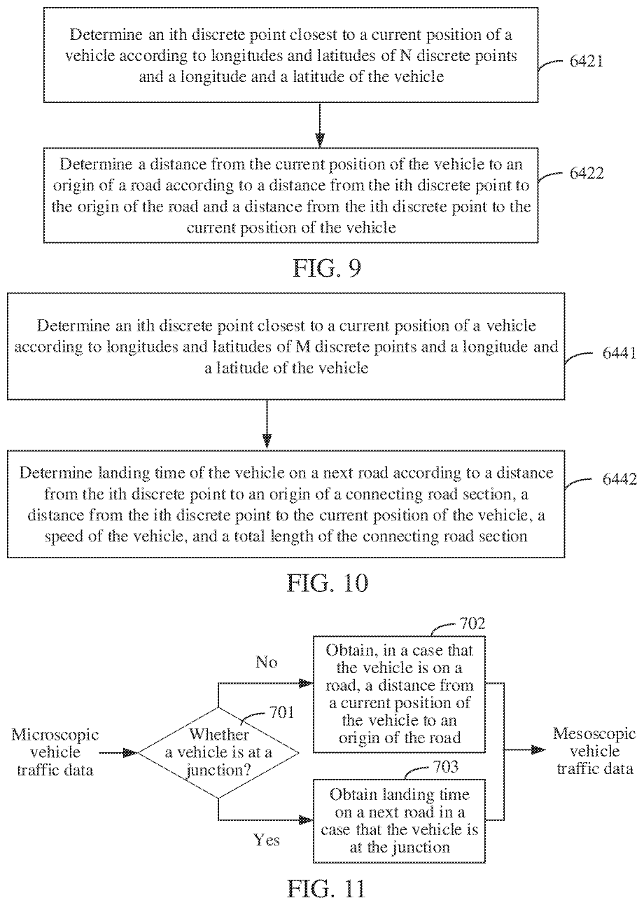

FIG. 9 is a flowchart of converting the vehicle traffic data of the vehicle in the microscopic traffic simulation to obtain a distance from the current position of the vehicle to an origin of the road in the mesoscopic traffic simulation according to an embodiment of this application.

Step 6421: Determine an i^{th} discrete point closest to the current position of the vehicle according to longitudes and latitudes of the N discrete points and the longitude and the latitude of the vehicle.

For example, information about the road that the vehicle is on, including the N discrete points P₁, P₂, . . . , and P_{N} on the road that the vehicle is on and longitudes and latitudes of the discrete points, is obtained by using a serial number of the road that the vehicle is on. The N discrete points are traversed to determine the i^{th} discrete point Pᵢ closest to the current position P_{vehicle} of the vehicle. i is a positive integer less than N.

That is, j making the following formula minimum is assigned to i:

min_{1<j<N}distance(P_{vehicle},Pⱼ),

where distance(P_{vehicle}, Pⱼ) represents a distance from the current position Pvehicle of the vehicle to a j^{th} discrete point Pⱼ, and j is a positive integer less than N.

Step 6422: Determine the distance from the current position of the vehicle to the origin of the road according to a distance from the i^{th} discrete point to the origin of the road and a distance from the i^{th} discrete point to the current position of the vehicle.

A calculation process for the distance from the i^{th} discrete point to the origin of the road is similar to that in step 4421 or step 4422. The distance from the i^{th} discrete point to the origin of the road is determined by accumulating distances between adjacent discrete points from the first discrete point P₁ to the i^{th} discrete point Pᵢ. Elaborations are omitted herein.

A sum of the obtained distance from the i^{th} discrete point to the origin of the road and the distance from the i^{th} discrete point to the current position of the vehicle is determined as the distance from the current position of the vehicle to the origin of the road. A specific calculation formula is as follows:

road_posₘₑₛₒ=dis_to_startᵢ+distance(P_{vehicle},Pᵢ),

where road_posₘₑₛₒ represents the distance from the current position of the vehicle to the origin of the road in the mesoscopic traffic simulation, dis_to_startᵢ represents the distance from the i^{th} discrete point to the origin of the road, and distance(P_{vehicle}, Pᵢ) represents the distance from the i^{th} discrete point to the current position of the vehicle. distance(P_{vehicle}, Pᵢ) may be positive or negative. When a direction of a connecting line of the i^{th} discrete point and the current position of the vehicle is the same as that of the road, distance(P_{vehicle}, Pᵢ) is positive. When a direction of a connecting line of the i^{th} discrete point and the current position of the vehicle is opposite to that of the road, distance(P_{vehicle}, Pᵢ) is negative.

Step 644: Perform conversion according to the serial number of the road section that the vehicle is on, the longitude and the latitude of the vehicle, and the speed of the vehicle to obtain landing time of the vehicle on a next road in the mesoscopic traffic simulation.

When the landing time of the vehicle on the next road is 0, the current position of the vehicle is on the road. When the landing time of the vehicle on the next road is greater than 0, the current position of the vehicle is on the connecting road section. Therefore, the landing time of the vehicle on the next road is usually vehicle traffic data to be obtained through conversion for the vehicle on the connecting road section.

For example, information about the connecting road section that the vehicle is on, including information about a discrete point on the connecting road section that the vehicle is on, is obtained by using a serial number of the connecting road section that the vehicle is on. A discrete point closest to the current position of the vehicle is determined according to the longitude and the latitude of the vehicle and a longitude and a latitude of the discrete point, and a distance from the discrete point to the origin of the connecting road section, that is, a distance from the current position of the vehicle to the origin of the connecting road section, is calculated. A total length of the connecting road section is determined according to the longitude and the latitude of the discrete point. Finally, the landing time of the vehicle on the next road is determined according to the total length of the connecting road section, the distance from the current position of the vehicle to the origin of the connecting road section, and the speed of the vehicle.

For example, the connecting road section in the microscopic traffic simulation includes M discrete points arranged in order, M being a positive integer.

The following describes step 644 more specifically. FIG. 10 is a flowchart of converting the vehicle traffic data of the vehicle in the microscopic traffic simulation to obtain the landing time of the vehicle on the next road in the mesoscopic traffic simulation according to an embodiment of this application.

Step 6441: Determine an i^{th} discrete point closest to the current position of the vehicle according to longitudes and latitudes of the M discrete points and the longitude and the latitude of the vehicle.

For example, the information about the connecting road section that the vehicle is on, including the M discrete points P₁, P₂, . . . , and P_{M} on the connecting road section that the vehicle is on and longitudes and latitudes of the discrete points, is obtained by using the serial number of the connecting road section that the vehicle is on. The M discrete points are traversed to determine the i^{th} discrete point Pᵢ closest to the current position P_{vehicle} of the vehicle. i is a positive integer less than N.

That is, j making the following formula minimum is assigned to i:

min_{1<j<M}(P_{vehicle},Pⱼ),

where (P_{vehicle}, Pⱼ) represents a distance from the current position P_{vehicle} of the vehicle to a j^{th} discrete point Pⱼ, and j is a positive integer less than M.

Step 6442: Determine the landing time of the vehicle on the next road according to a distance from the i^{th} discrete point to an origin of the connecting road section, a distance from the i^{th} discrete point to the current position of the vehicle, the speed of the vehicle, and the total length of the connecting road section.

For example, step 6442 may be split into the following sub-steps:

(1): Obtain a distance between adjacent discrete points in the M discrete points according to the serial number of the connecting road section that the vehicle is on.

For example, search is performed in a microscopic map for the connecting road section that the vehicle is on according to the serial number road_id_{micro} of the connecting road section that the vehicle is on in the first vehicle traffic data. The connecting road section includes the M discrete points P₁, P₂, . . . , and P_{M} arranged in order. P1 is the origin of the connecting road section. The distance between the adjacent discrete points in the M discrete points is obtained.

Like the road, each connecting road section has direction information. That is, an origin P1 of each connecting road section is uniquely determined.

(2): Determine the distance from the i^{th} discrete point to the origin of the connecting road section and the total length of the connecting road section by accumulating the distance between the adjacent discrete points.

For example, the distance dis_to_startᵢ from the i^{th} discrete point to the origin of the connecting road section and the total length (length) of the connecting road section are calculated by accumulating the distance between the adjacent discrete points from the origin P₁ of the connecting road section. The total length of the connecting road section is a distance from an N^{th} discrete point P_{N} to the origin of the connecting road section.

For example, the distance dis_to_startᵢ from the i^{th} discrete point to the origin of the connecting road section is determined by accumulating distances between adjacent discrete points from the first discrete point P₁ to the i^{th} discrete point Pᵢ. The distance dis_to_start_{N} from the N^{th} discrete point to the origin of the connecting road section, that is, the total length (length) of the connecting road section, is determined by accumulating distances between adjacent discrete points from the first discrete point P₁ to the N^{th} discrete point P_{N}. Specific calculation formulas are as follows:

dis_to_startᵢ=dis_to_startᵢ₋₁+distance(pᵢ₋₁,pᵢ), and

length=dis_to_start_{N}=dis_to_start_{N-1}+distance(p_{N-1},p_{N}),

where dis_to_startᵢ₋₁ represents a distance from an (i−1)^{th} discrete point Pᵢ₋₁ to the origin of the connecting road section, distance(pᵢ₋₁, pᵢ) represents a distance from the (i−1)^{th} discrete point Pᵢ₋₁ to the i^{th} discrete point Pᵢ, i being a positive integer less than N, dis_to_start_{N-1} represents a distance from an (N−1)^{th} discrete point P_{N-1} to the origin of the connecting road section, and distance(p_{N-1}, p_{N}) represents a distance from the (N−1)^{th} discrete point P_{N-1} to the N^{th} discrete point P_{N}.

Since the distance between the adjacent discrete points is short, a road bend and other factors may be ignored, and the distance between the adjacent discrete points is approximately represented by a straight line length.

(3): Determine a distance from the vehicle to the next road according to the total length of the connecting road section, the distance from the i^{th} discrete point to the origin of the connecting road section, and the distance from the i^{th} discrete point to the current position of the vehicle.

For example, the distance dis_to_next from the vehicle to the next road may be obtained by subtracting, from the total length (length) of the connecting road section, the distance dis_to_startᵢ from the i^{th} discrete point to the origin of the connecting road section and then the distance from the i^{th} discrete point to the current position of the vehicle. A specific formula is as follows:

dis_to_next=length−dis_to_startᵢ−distance(p_{vehicle},pᵢ).

distance(P_{vehicle}, Pᵢ) may be positive or negative. When a direction of a connecting line of the i^{th} discrete point and the current position of the vehicle is the same as that of the road, distance(P_{vehicle}, Pᵢ) is positive. When a direction of a connecting line of the i^{th} discrete point and the current position of the vehicle is opposite to that of the road, distance(P_{vehicle}, Pᵢ) is negative.

(4): Determine the landing time of the vehicle on the next road according to the distance from the vehicle to the next road and the speed of the vehicle.

For example, the landing time of the vehicle on the next road is obtained by dividing the distance dis_to_next from the vehicle to the next road by the speed of the vehicle. A specific formula is as follows:

$$\begin{matrix}{landing\_time}_{meso} = dis\_to \_next / {speed}_{mirco} \\ = [ length - {dis}_{{to}_{{start}_{i}}} - distance ( {p}_{vehicle} , {p}_{i} ) ] / {speed}_{mirco} .\end{matrix}$$

In a possible implementation, the total length (length) of the connecting road section is a part of map data. That is, data about the total length of the connecting road section may be directly obtained through searching according to the serial number of the road section that the vehicle is on, and the calculation process in sub-step (3) in which the total length of the connecting road section is obtained by accumulating the distance between the adjacent discrete points is not required.

In a possible implementation, the road section in the microscopic map is described by using a function. That is, a sub-step of sampling the function for describing the road section to obtain the discrete points is added before sub-step (1).

When a type of the road section that the vehicle is on is the road, the landing time of the vehicle on the next road in the mesoscopic vehicle traffic data is 0, so that a relative position of the vehicle on the road in the mesoscopic traffic simulation is usually indicated by using the distance from the current position of the vehicle to the origin of the road, that is, step 642 is performed. When a type of the road section that the vehicle is on is the connecting road section, more attention is usually paid to the landing time of the vehicle on the next road, that is, step 644 is performed.

In another possible implementation, when a type of the road section that the vehicle is on is the road, step 642 is performed. When a type of the road section that the vehicle is on is the connecting road section, step 642 and step 644 are performed.

In another possible implementation, no matter whether a type of the road section that the vehicle is on is the road or the connecting road section, step 642 is performed.

Step 662: Run the mesoscopic traffic simulation according to the second vehicle traffic data of the vehicle.

For example, the mesoscopic traffic simulation is run based on the obtained distance from the current position of the vehicle to the origin of the road and the landing time of the vehicle on the next road.

The mesoscopic traffic simulation focuses not on a traffic behavior of each mesoscopic vehicle but on a traffic condition of a road section level, for example, a traffic flow on the road section, an average speed, or a traffic index. Each mesoscopic vehicle in the mesoscopic traffic simulation belongs to a queue.

For example, the vehicle is added to a corresponding position in the queue to which the vehicle belongs according to the distance from the current position of the vehicle to the origin of the road. The mesoscopic traffic simulation is run based on a queue model.

In addition, the process of converting the microscopic traffic simulation to the mesoscopic traffic simulation in the traffic simulation conversion method of this application may be more directly presented by using an input information flow and an output information flow.

FIG. 11 is a flowchart of converting the microscopic traffic simulation to the mesoscopic traffic simulation according to an embodiment of this application.

It can be seen from FIG. 11 that the input information flow is microscopic vehicle traffic data, specifically a serial number of a road section that a microscopic vehicle is on and a longitude and a latitude of the microscopic vehicle.

Step 701: Determine whether the vehicle is at a junction. If the vehicle is not at the junction, step 702 is performed; or if the vehicle is at the junction, step 703 is performed.

Step 702: Obtain, when the vehicle is on a road, a distance from a current position of the vehicle to an origin of the road according to the method in step 642 in the foregoing embodiment.

Step 703: Obtain, when the vehicle is at the junction, landing time on a next road according to the method in step 644 in the foregoing embodiment.

Finally, the output information flow in the traffic simulation conversion method in this embodiment of this application is mesoscopic vehicle traffic data, specifically the distance from the current position of the vehicle to the origin of the road and the landing time of the vehicle at the junction on the next road.

In summary, in this embodiment of this application, conversion from the microscopic traffic simulation to the mesoscopic traffic simulation is implemented by obtaining information about the discrete point on the road section that the vehicle is on and converting the vehicle traffic data of the microscopic vehicle to the vehicle traffic data of the mesoscopic vehicle in combination with the longitude and the latitude of the vehicle and the speed of the vehicle. In the method, a method for converting a microscopic traffic simulation to a mesoscopic traffic simulation is provided. All vehicles are traversed, and conversion is performed according to vehicle traffic data of each vehicle. Therefore, consistency of data before and after conversion is ensured, the problem of a deviation between traffic conditions before and after conversion is solved, and traffic simulation conversion accuracy is improved.

In addition, the road section is represented by discrete points, so that traffic simulation conversion may be implemented at any position of the road section. This may not only implement conversion for an entire region but also run different traffic simulation modes for different regions at the same moment. Therefore, flexibility is high.

Moreover, the vehicle traffic data of the mesoscopic vehicle, the vehicle traffic data of the microscopic vehicle, and the microscopic map, on which this method is based, are all simply represented, and may be easily applied to conversion of various microscopic traffic simulations and mesoscopic traffic simulations. For example, the vehicle traffic data of the mesoscopic vehicle, on which this method is based, is applicable to a flow density-speed model and the queue model in the mesoscopic traffic simulation. For another example, the vehicle traffic data of the microscopic vehicle, on which this method is based, may be compatible with vehicle traffic data in commonly used software such as sumo and vissim in the field of traffic simulation technologies.

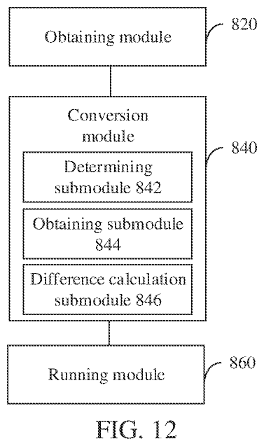

FIG. 12 is a block diagram of a structure of a traffic simulation conversion apparatus according to an embodiment of this application. As shown in FIG. 12, the apparatus includes:
an obtaining module 820, configured to obtain first vehicle traffic data of a vehicle in a first traffic simulation;
a conversion module 840, configured to perform conversion according to the first vehicle traffic data to obtain second vehicle traffic data of the vehicle in a second traffic simulation; and
a running module 860, configured to run the second traffic simulation according to the second vehicle traffic data of the vehicle.

The first traffic simulation and the second traffic simulation include one of a microscopic traffic simulation and a mesoscopic traffic simulation respectively. The first traffic simulation is different from the second traffic simulation.

In a possible embodiment, the first traffic simulation includes the mesoscopic traffic simulation, and the second traffic simulation includes the microscopic traffic simulation. The obtaining module 820 is configured to obtain the first vehicle traffic data of the vehicle in the mesoscopic traffic simulation. The first vehicle traffic data includes a serial number of a road section that the vehicle is on and a distance from a current position of the vehicle to an origin of the road section. The conversion module 840 is configured to perform conversion according to the serial number of the road section that the vehicle is on and the distance from the current position of the vehicle to the origin of the road section to obtain the second vehicle traffic data of the vehicle in the microscopic traffic simulation. The second vehicle traffic data includes a longitude and a latitude of the vehicle and a front orientation of the vehicle.

In a possible embodiment, the conversion module 840 includes a determining submodule 842. The determining submodule 842 is configured to determine, when a type of the road section that the vehicle is on is a road, the longitude and the latitude of the vehicle according to a serial number of the road that the vehicle is on and a distance from the current position of the vehicle to an origin of the road, and determine the front orientation of the vehicle according to the serial number of the road that the vehicle is on and the distance from the current position of the vehicle to the origin of the road; or determine, when a type of the road section that the vehicle is on is a connecting road section, the longitude and the latitude of the vehicle according to a serial number of the connecting road section that the vehicle is on and a distance from the current position of the vehicle to an origin of the connecting road section, and determine the front orientation of the vehicle according to the serial number of the connecting road section that the vehicle is on and the distance from the current position of the vehicle to the origin of the connecting road section.

In a possible embodiment, the road in the microscopic traffic simulation includes N discrete points arranged in order, N being a positive integer. The determining submodule 842 is configured to determine, when the type of the road section that the vehicle is on is the road, a longitude and a latitude of an i^{th} discrete point closest to the current position of the vehicle in the N discrete points in the road as the longitude and the latitude of the vehicle according to the serial number of the road that the vehicle is on and the distance from the current position of the vehicle to the origin of the road, i being a positive integer less than N.

In a possible embodiment, the conversion module 840 includes an obtaining submodule 844 and a difference calculation submodule 846. The obtaining submodule 844 is configured to obtain a distance between adjacent discrete points in the N discrete points according to the serial number of the road that the vehicle is on. The determining submodule 842 is configured to determine a distance from each of the N discrete points in the road to the origin of the road by accumulating the distance between the adjacent discrete points. The difference calculation submodule 846 is configured to calculate a difference between the distance from each of the N discrete points to the origin of the road and the distance from the current position of the vehicle to the origin of the road. The determining submodule 842 is configured to determine the longitude and the latitude of the i^{th} discrete point corresponding to a minimum difference as the longitude and the latitude of the vehicle, i being a positive integer less than or equal to N.

In a possible embodiment, the connecting road section in the microscopic traffic simulation includes M discrete points arranged in order, M being a positive integer. That the determining submodule 842 is configured to determine, when a type of the road section that the vehicle is on is a connecting road section, the longitude and the latitude of the vehicle according to a serial number of the connecting road section that the vehicle is on and a distance from the current position of the vehicle to an origin of the connecting road section includes that: the determining submodule 842 is configured to determine, when the type of the road section that the vehicle is on is the connecting road section, a longitude and a latitude of an i^{th} discrete point closest to the current position of the vehicle in the M discrete points in the connecting road section as the longitude and the latitude of the vehicle according to the serial number of the connecting road section that the vehicle is on and the distance from the current position of the vehicle to the origin of the connecting road section, i being a positive integer less than N.

In a possible embodiment, the obtaining submodule 844 is configured to obtain a distance between adjacent discrete points in the M discrete points according to the serial number of the connecting road section that the vehicle is on. The determining submodule 842 is configured to determine a distance from each of the M discrete points in the connecting road section to the origin of the connecting road section by accumulating the distance between the adjacent discrete points. The difference calculation submodule 846 is configured to calculate a difference between the distance from each of the M discrete points to the origin of the connecting road section and the distance from the current position of the vehicle to the origin of the connecting road section. The determining submodule 842 is configured to determine the longitude and the latitude of the i^{th} discrete point corresponding to a minimum difference as the longitude and the latitude of the vehicle, i being a positive integer less than or equal to M.

In a possible embodiment, the determining submodule 842 is configured to determine the front orientation of the vehicle according to the i^{th} discrete point and an (i−1)th discrete point.

In a possible embodiment, the first traffic simulation includes the microscopic traffic simulation, and the second traffic simulation includes the mesoscopic traffic simulation. The obtaining module 820 is configured to obtain the first vehicle traffic data of the vehicle in the microscopic traffic simulation. The first vehicle traffic data includes a serial number of a road section that the vehicle is on, a longitude and a latitude of the vehicle, and a speed of the vehicle. The conversion module 840 is configured to perform at least one of the following operations: performing conversion according to the serial number of the road section that the vehicle is on and the longitude and the latitude of the vehicle to obtain a distance from a current position of the vehicle to an origin of the road section in the mesoscopic traffic simulation; and performing conversion according to the serial number of the road section that the vehicle is on, the longitude and the latitude of the vehicle, and the speed of the vehicle to obtain landing time of the vehicle on a next road in the mesoscopic traffic simulation.

In a possible embodiment, a road in the microscopic traffic simulation includes N discrete points arranged in order, N being a positive integer. The determining submodule 842 is configured to determine an i^{th} discrete point closest to the current position of the vehicle according to longitudes and latitudes of the N discrete points and the longitude and the latitude of the vehicle, i being a positive integer less than N, and determine the distance from the current position of the vehicle to the origin of the road according to a distance from the i^{th} discrete point to the origin of the road and a distance from the i^{th} discrete point to the current position of the vehicle.

In a possible embodiment, a connecting road section in the microscopic traffic simulation includes M discrete points arranged in order, M being a positive integer. The determining submodule 842 is configured to determine an i^{th} discrete point closest to the current position of the vehicle according to longitudes and latitudes of the M discrete points and the longitude and the latitude of the vehicle, i being a positive integer less than M. The determining submodule 842 is configured to determine the landing time of the vehicle on the next road according to a distance from the i^{th} discrete point to an origin of the connecting road section, a distance from the i^{th} discrete point to the current position of the vehicle, the speed of the vehicle, and a total length of the connecting road section.

In a possible embodiment, the obtaining submodule 844 is configured to obtain a distance between adjacent discrete points in the M discrete points according to the serial number of the connecting road section that the vehicle is on. The determining submodule 842 is configured to determine the distance from the i^{th} discrete point to the origin of the connecting road section and the total length of the connecting road section by accumulating the distance between the adjacent discrete points. The determining submodule 842 is configured to determine a distance from the vehicle to the next road according to the total length of the connecting road section, the distance from the i^{th} discrete point to the origin of the connecting road section, and the distance from the i^{th} discrete point to the current position of the vehicle. The determining submodule 842 is configured to determine the landing time of the vehicle on the next road according to the distance from the vehicle to the next road and the speed of the vehicle.

In a possible embodiment, the obtaining module 820 is configured to obtain a microscopic traffic simulation region. The running module 860 is configured to display the microscopic traffic simulation in the microscopic traffic simulation region, display the mesoscopic traffic simulation in a mesoscopic traffic simulation region other than the microscopic traffic simulation region, and display vehicle traffic data in the microscopic traffic simulation region.

In a possible embodiment, the obtaining module 820 is configured to determine, in response to a traffic prediction operation, vehicle traffic data in the mesoscopic traffic simulation based on vehicle traffic data in the microscopic traffic simulation. The conversion module 840 is configured to convert, for a vehicle in a prediction region, the microscopic traffic simulation to the mesoscopic traffic simulation. The running module 860 is configured to display a predicted traffic status.

It is to be noted that division of the functional modules of the traffic simulation conversion apparatus provided in the foregoing embodiment is used merely as an example for description. In actual applications, depending on a requirement, the functions may be allocated to different functional modules for implementation, that is, an internal structure of the apparatus is divided into different functional modules to implement all or some of the functions described above.

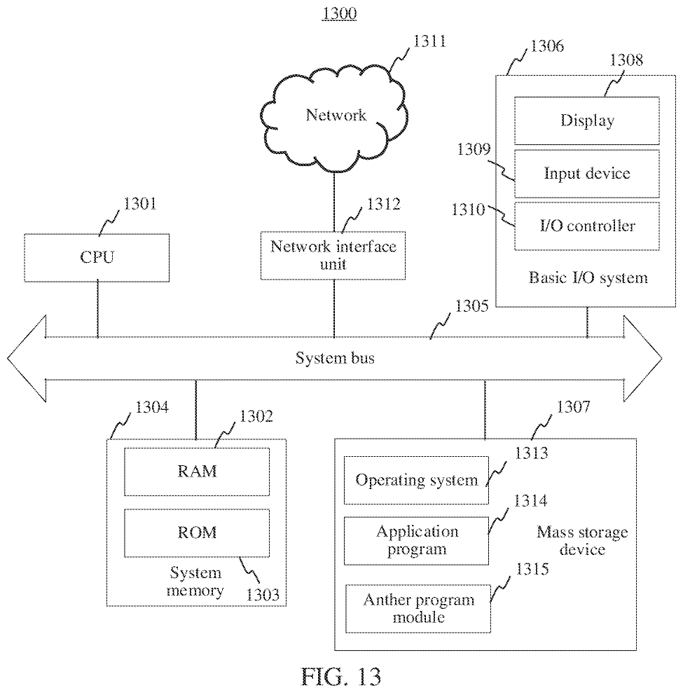

FIG. 13 is a schematic diagram of a structure of a computer device according to an embodiment. The computer device 1300 includes a central processing unit (CPU) 1301, a system memory 1304 including a random access memory (RAM) 1302 and a read-only memory (ROM) 1303, and a system bus 1305 that connects the system memory 1304 to the CPU 1301. The computer device 1300 further includes a basic input/output (I/O) system 1306 that helps information transmission between devices in the computer device, and a mass storage device 1307 configured to store an operating system 1313, an application program 1314, and another program module 1315.

The basic I/O system 1306 includes a display 1308 configured to display information and an input device 1309 configured for a user to input information, for example, a mouse or a keyboard. Both the display 1308 and the input device 1309 are connected to the CPU 1301 by using an I/O controller 1310 connected to the system bus 1305. The basic I/O system 1306 may further include the I/O controller 1310 configured to receive and process inputs of a plurality of other devices, for example, the keyboard, the mouse, or an electronic stylus. Similarly, the I/O controller 1310 further provides an output to a display screen, a printer, or another type of output device.

The mass storage device 1307 is connected to the CPU 1301 by using a mass storage controller (not shown) connected to the system bus 1305. The mass storage device 1307 and a computer device readable medium associated therewith provide non-volatile storage for the computer device 1300. That is, the mass storage device 1307 may include the computer device readable medium (not shown), for example, a hard disk or a compact disc read-only memory (CD-ROM).

Without loss of generality, the computer device readable medium may include a computer device storage medium and a communication medium. The computer device storage medium includes volatile/nonvolatile and removable/irremovable media implemented by any method or technology for storing information, for example, computer device readable instructions, a data structure, a program module, or other data. The computer device storage medium includes a RAM, a ROM, an erasable programmable read-only memory (EPROM), an electrically erasable programmable read-only memory (EEPROM), a CD-ROM, a digital video disc (DVD) or another optical storage, a cassette tape, a magnetic tape, and a disk memory or another magnetic storage device. Certainly, it may be known by a person skilled in the art that the computer device storage medium is not limited to the foregoing. The system memory 1304 and the mass storage device 1307 may be collectively referred to as memories.

According to various embodiments of the present disclosure, the computer device 1300 may further be connected, by using a network such as the Internet, to a remote computer device on the network for running. That is, the computer device 1300 may be connected to a network 1311 through a network interface unit 1312 connected to the system bus 1305, or may be connected to another type of network or a remote computer device system (not shown) through a network interface unit 1312.

The memory further includes one or more programs. The one or more programs are stored in the memory. The CPU 1301 executes the one or more programs to implement all or some steps of the traffic simulation conversion method. An embodiment of this application also provides a computer-readable storage medium. The computer-readable storage medium stores at least one instruction, at least one piece of program, a code set, or an instruction set. The at least one instruction, the at least one piece of program, the code set, or the instruction set is loaded and executed by a processor to implement the traffic simulation conversion method provided in each of the foregoing method embodiments.

An embodiment of this application also provides a computer program product or computer program. The computer program product or computer program includes computer instructions. The computer instructions are stored in a computer-readable storage medium. A processor of a computer device reads the computer instructions from the computer-readable storage medium. The processor executes the computer instructions, such that the computer device performs any traffic simulation conversion method as described in the foregoing embodiments.

Optionally, the computer-readable storage medium may include a ROM, a RAM, a solid state drive (SSD), an optical disk, or the like. The RAM may include a resistance random access memory (ReRAM) and a dynamic random access memory (DRAM). The sequence numbers of the embodiments of this application are only for description and do not represent superiority-inferiority of the embodiments.

What is claimed is:

1. A traffic simulation conversion method, the method being performed by a computer device, and the method comprising:
obtaining first vehicle traffic data of a vehicle in a first traffic simulation;
performing conversion according to the first vehicle traffic data to obtain second vehicle traffic data of the vehicle in a second traffic simulation; and
running the second traffic simulation according to the second vehicle traffic data of the vehicle,
wherein the first traffic simulation and the second traffic simulation comprises one of a microscopic traffic simulation and a mesoscopic traffic simulation, and the first traffic simulation is different from the second traffic simulation.

2. The method according to claim 1, wherein the first traffic simulation comprises the mesoscopic traffic simulation, and the second traffic simulation comprises the microscopic traffic simulation;
obtaining first vehicle traffic data of a vehicle in a first traffic simulation comprises:
obtaining the first vehicle traffic data of the vehicle in the mesoscopic traffic simulation, the first vehicle traffic data comprising a serial number of a road section that the vehicle is on and a distance from a current position of the vehicle to an origin of the road section that the vehicle is on; and
performing conversion according to the first vehicle traffic data to obtain second vehicle traffic data of the vehicle in a second traffic simulation comprises:
performing conversion according to the serial number of the road section that the vehicle is on and the distance from the current position of the vehicle to the origin of the road section that the vehicle is on to obtain the second vehicle traffic data of the vehicle in the microscopic traffic simulation, the second vehicle traffic data comprising a longitude and a latitude of the vehicle and a front orientation of the vehicle.

3. The method according to claim 2, wherein performing conversion according to the serial number of the road section that the vehicle is on and the distance from the current position of the vehicle to the origin of the road section that the vehicle is on to obtain the second vehicle traffic data of the vehicle in the microscopic traffic simulation comprises:
determining, when a type of the road section that the vehicle is on is a road, the longitude and the latitude of the vehicle according to a serial number of a road that the vehicle is on and a distance from the current position of the vehicle to an origin of the road that the vehicle is on; or
determining, when a type of the road section that the vehicle is on is a connecting road section, the longitude and the latitude of the vehicle according to a serial number of a connecting road section that the vehicle is on and a distance from the current position of the vehicle to an origin of the connecting road section that the vehicle is on.

4. The method according to claim 3, wherein the road that the vehicle is on in the microscopic traffic simulation comprises N discrete points arranged in order, N being a positive integer; and
determining the longitude and the latitude of the vehicle according to the serial number of the road that the vehicle is on and the distance from the current position of the vehicle to an origin of the road that the vehicle is on comprises:
determining, when the type of the road section that the vehicle is on is a road, a longitude and a latitude of an i^{th} discrete point closest to the current position of the vehicle in the N discrete points in the road that the vehicle is on as the longitude and the latitude of the vehicle according to the serial number of the road that the vehicle is on and the distance from the current position of the vehicle to the origin of the road that the vehicle is on, i being a positive integer less than N.

5. The method according to claim 4, wherein determining a longitude and a latitude of an i^{th} discrete point closest to the current position of the vehicle in the N discrete points in the road that the vehicle is on as the longitude and the latitude of the vehicle according to the serial number of the road that the vehicle is on and the distance from the current position of the vehicle to the origin of the road that the vehicle is on comprises:
obtaining a distance between adjacent discrete points in the N discrete points according to the serial number of the road that the vehicle is on;
determining a distance from each of the N discrete points in the road that the vehicle is on to the origin of the road that the vehicle is on by accumulating the distance between the adjacent discrete points;
calculating a difference between the distance from each of the N discrete points to the origin of the road that the vehicle is on and the distance from the current position of the vehicle to the origin of the road that the vehicle is on; and
determining the longitude and the latitude of the i^{th} discrete point corresponding to a minimum difference as the longitude and the latitude of the vehicle, i being a positive integer less than or equal to N.

6. The method according to claim 3, wherein connecting road section that the vehicle is on in the microscopic traffic simulation comprises M discrete points arranged in order, M being a positive integer; and
determining the longitude and the latitude of the vehicle according to a serial number of the connecting road section that the vehicle is on and a distance from the current position of the vehicle to an origin of the connecting road section that the vehicle is on comprises:
determining a longitude and a latitude of an i^{th} discrete point closest to the current position of the vehicle in the M discrete points in the connecting road section that the vehicle is on as the longitude and the latitude of the vehicle according to the serial number of the connecting road section that the vehicle is on and the distance from the current position of the vehicle to the origin of the connecting road section that the vehicle is on, i being a positive integer less than M.

7. The method according to claim 6, wherein determining a longitude and a latitude of an i^{th} discrete point closest to the current position of the vehicle in the M discrete points in the connecting road section that the vehicle is on as the longitude and the latitude of the vehicle according to the serial number of the connecting road section that the vehicle is on and the distance from the current position of the vehicle to the origin of the connecting road section that the vehicle is on comprises:
obtaining a distance between adjacent discrete points in the M discrete points according to the serial number of the connecting road section that the vehicle is on;
determining a distance from each of the M discrete points in the connecting road section that the vehicle is on to the origin of the connecting road section that the vehicle is on by accumulating the distance between the adjacent discrete points;
calculating a difference between the distance from each of the M discrete points to the origin of the connecting road section that the vehicle is on and the distance from the current position of the vehicle to the origin of the connecting road section that the vehicle is on; and
determining the longitude and the latitude of the i^{th} discrete point corresponding to a minimum difference as the longitude and the latitude of the vehicle, i being a positive integer less than or equal to M.

8. The method according to claim 2, wherein performing conversion according to the serial number of the road section that the vehicle is on and the distance from the current position of the vehicle to the origin of the road section that the vehicle is on to obtain the second vehicle traffic data of the vehicle in the microscopic traffic simulation comprises:
determining the front orientation of the vehicle according to a serial number of a road that the vehicle is on and a distance from the current position of the vehicle to an origin of the road that the vehicle is on.

9. The method according to claim 8, wherein determining the front orientation of the vehicle according to a serial number of a road that the vehicle is on and a distance from the current position of the vehicle to an origin of the road that the vehicle is on comprises:
determining an i^{th} discrete point closest to the current position of the vehicle according to the serial number of the road that the vehicle is on and the distance from the current position of the vehicle to the origin of the road that the vehicle is on; and
determining the front orientation of the vehicle according to the i^{th} discrete point and an (i−1)^{th} discrete point, i being an integer less than N+1 and greater than 1.

10. The method according to claim 1, wherein the first traffic simulation comprises the microscopic traffic simulation, and the second traffic simulation comprises the mesoscopic traffic simulation;
obtaining first vehicle traffic data of a vehicle in a first traffic simulation comprises:
obtaining the first vehicle traffic data of the vehicle in the microscopic traffic simulation, the first vehicle traffic data comprising a serial number of a road section that the vehicle is on, a longitude and a latitude of the vehicle, and a speed of the vehicle; and
performing conversion according to the first vehicle traffic data to obtain second vehicle traffic data of the vehicle in a second traffic simulation comprises at least one of the following operations:
performing conversion according to the serial number of the road section that the vehicle is on and the longitude and the latitude of the vehicle to obtain a distance from a current position of the vehicle to an origin of the road section that the vehicle is on in the mesoscopic traffic simulation; and
performing conversion according to the serial number of the road section that the vehicle is on, the longitude and the latitude of the vehicle, and the speed of the vehicle to obtain landing time of the vehicle on a next road in the mesoscopic traffic simulation.

11. The method according to claim 10, wherein the road that the vehicle is on comprises N discrete points, N being a positive integer; and
determining a distance from the current position of the vehicle to an origin of the road that the vehicle is on according to a serial number of the road that the vehicle is on and the longitude and the latitude of the vehicle comprises:
determining an i^{th} discrete point closest to the current position of the vehicle according to longitudes and latitudes of the N discrete points and the longitude and the latitude of the vehicle, i being a positive integer less than N; and
determining the distance from the current position of the vehicle to the origin of the road that the vehicle is on according to a distance from the i^{th} discrete point to the origin of the road that the vehicle is on and a distance from the i^{th} discrete point to the current position of the vehicle.

12. The method according to claim 10, wherein a connecting road section that the vehicle is on comprises M discrete points arranged in order, M being a positive integer; and
determining of the landing time of the vehicle on the next road according to a serial number of the connecting road section that the vehicle is on, the longitude and the latitude of the vehicle, and the speed of the vehicle comprises:
determining an i^{th} discrete point closest to the current position of the vehicle according to longitudes and latitudes of the M discrete points and the longitude and the latitude of the vehicle, i being a positive integer less than M; and
determining, according to a distance from the i^{th} discrete point to an origin of the connecting road section that the vehicle is on, a distance from the i^{th} discrete point to the current position of the vehicle, the speed of the vehicle, and a total length of the connecting road section that the vehicle is on, the landing time of the vehicle on the next road.

13. The method according to claim 1, wherein the method further comprises:
obtaining a microscopic traffic simulation region;
displaying the microscopic traffic simulation in the microscopic traffic simulation region, and displaying the mesoscopic traffic simulation in a mesoscopic traffic simulation region other than the microscopic traffic simulation region; and
displaying microscopic vehicle traffic data in the microscopic traffic simulation region, and displaying mesoscopic vehicle traffic data in the mesoscopic traffic simulation region, the microscopic vehicle traffic data being vehicle traffic data of a microscopic vehicle, and the mesoscopic vehicle traffic data being vehicle traffic data of a mesoscopic vehicle.

14. The method according to claim 1, wherein the method further comprises:
determining, in response to a traffic prediction operation, mesoscopic vehicle traffic data in the mesoscopic traffic simulation based on microscopic vehicle traffic data in the microscopic traffic simulation;
converting, for a vehicle in a prediction region, the microscopic traffic simulation to the mesoscopic traffic simulation according to the microscopic vehicle traffic data and the mesoscopic vehicle traffic data; and
displaying a predicted traffic status according to the mesoscopic traffic simulation.

15. A traffic simulation conversion apparatus, the apparatus comprising:
a processor; and
a non-transitory computer readable memory in communication with the processor and storing a plurality of instructions, the plurality of instructions, when executed by the processor, configure the processor to:
obtain first vehicle traffic data of a vehicle in a first traffic simulation;
perform conversion according to the first vehicle traffic data to obtain second vehicle traffic data of the vehicle in a second traffic simulation; and
run the second traffic simulation according to the second vehicle traffic data of the vehicle,
the first traffic simulation and the second traffic simulation comprising one of a microscopic traffic simulation and a mesoscopic traffic simulation, and the first traffic simulation being different from the second traffic simulation.

16. The apparatus according to claim 15, wherein the first traffic simulation comprises the mesoscopic traffic simulation, and the second traffic simulation comprises the microscopic traffic simulation;
wherein the plurality of instructions further configure the processor to:
obtain the first vehicle traffic data of the vehicle in the mesoscopic traffic simulation, the first vehicle traffic data comprising a serial number of a road section that the vehicle is on and a distance from a current position of the vehicle to an origin of the road section that the vehicle is on; and
perform conversion according to the serial number of the road section that the vehicle is on and the distance from the current position of the vehicle to the origin of the road section that the vehicle is on to obtain the second vehicle traffic data of the vehicle in the microscopic traffic simulation, the second vehicle traffic data comprising a longitude and a latitude of the vehicle and a front orientation of the vehicle.

17. The apparatus according to claim 15, wherein the first traffic simulation comprises the microscopic traffic simulation, and the second traffic simulation comprises the mesoscopic traffic simulation; and
wherein the plurality of instructions further configure the processor to:
obtain the first vehicle traffic data of the vehicle in the microscopic traffic simulation, the first vehicle traffic data comprising a serial number of a road section that the vehicle is on, a longitude and a latitude of the vehicle, and a speed of the vehicle; and
perform at least one of the following operations: performing conversion according to the serial number of the road section that the vehicle is on and the longitude and the latitude of the vehicle to obtain a distance from a current position of the vehicle to an origin of the road section that the vehicle is on in the mesoscopic traffic simulation, and performing conversion according to the serial number of the road section that the vehicle is on, the longitude and the latitude of the vehicle, and the speed of the vehicle to obtain landing time of the vehicle on a next road in the mesoscopic traffic simulation.

18. A non-transitory computer readable memory in communication with a processor and storing a plurality of instructions, the plurality of instructions, when executed by the processor, configure the processor to:
obtain first vehicle traffic data of a vehicle in a first traffic simulation;
perform conversion according to the first vehicle traffic data to obtain second vehicle traffic data of the vehicle in a second traffic simulation; and
run the second traffic simulation according to the second vehicle traffic data of the vehicle,
the first traffic simulation and the second traffic simulation comprising one of a microscopic traffic simulation and a mesoscopic traffic simulation, and the first traffic simulation being different from the second traffic simulation.

19. The non-transitory computer readable memory according to claim 18, wherein the first traffic simulation comprises the mesoscopic traffic simulation, and the second traffic simulation comprises the microscopic traffic simulation;
wherein the plurality of instructions further configure the processor to:
obtain the first vehicle traffic data of the vehicle in the mesoscopic traffic simulation, the first vehicle traffic data comprising a serial number of a road section that the vehicle is on and a distance from a current position of the vehicle to an origin of the road section that the vehicle is on; and
perform conversion according to the serial number of the road section that the vehicle is on and the distance from the current position of the vehicle to the origin of the road section that the vehicle is on to obtain the second vehicle traffic data of the vehicle in the microscopic traffic simulation, the second vehicle traffic data comprising a longitude and a latitude of the vehicle and a front orientation of the vehicle.

20. The non-transitory computer readable memory according to claim 18, wherein the first traffic simulation comprises the microscopic traffic simulation, and the second traffic simulation comprises the mesoscopic traffic simulation; and
wherein the plurality of instructions further configure the processor to:
obtain the first vehicle traffic data of the vehicle in the microscopic traffic simulation, the first vehicle traffic data comprising a serial number of a road section that the vehicle is on, a longitude and a latitude of the vehicle, and a speed of the vehicle; and
perform at least one of the following operations: performing conversion according to the serial number of the road section that the vehicle is on and the longitude and the latitude of the vehicle to obtain a distance from a current position of the vehicle to an origin of the road section that the vehicle is on in the mesoscopic traffic simulation, and performing conversion according to the serial number of the road section that the vehicle is on, the longitude and the latitude of the vehicle, and the speed of the vehicle to obtain landing time of the vehicle on a next road in the mesoscopic traffic simulation.
